(19) United States
(12) Patent Application Publication
(10) Pub. No.: US 2006/0246718 A1
(43) Pub. Date: Nov. 2, 2006

(54) Technique for forming self-aligned vias in a metallization layer

(76) Inventors: Kai Frohberg, Niederau (DE); Matthias Lehr, Dresden (DE); Holger Schuehrer, Dresden (DE)

Correspondence Address: WILLIAMS, MORGAN & AMERSON, 10333 RICHMOND, SUITE 1100, HOUSTON, TX, 77042, US

(21) Appl. No.: 11/292,044

(22) Filed: Dec. 1, 2005

(30) Foreign Application Priority Data
Apr. 29, 2005 (DE) 10 2005 020 132.6

(51) Int. Cl. H01L 21/4763

(52) U.S. Cl. 438/638

(57) ABSTRACT

By designing trenches with portions of increased width, via structures formed after the trench etch process may be etched on the basis of sidewall spacers in the portions of increased widths, thereby rendering a further photolithography process for defining via openings obsolete. Consequently, high alignment precision with reduced process complexity is achieved.

### BACKGROUND OF THE INVENTION

1. Field of the Invention

Generally, the present invention relates to the formation of integrated circuits, and, more particularly, to the formation of metallization layers including conductive metals, such as copper, embedded into a dielectric material according to the damascene approach.

2. Description of the Related Art

In an integrated circuit, a huge number of circuit elements, such as transistors, capacitors, resistors and the like, are formed in or on an appropriate substrate, usually in a substantially planar configuration. Due to the large number of circuit elements and the required complex layout of the integrated circuits, generally the electrical connection of the individual circuit elements may not be established within the same level on which the circuit elements are manufactured, but requires one or more additional “wiring” layers, also referred to as metallization layers. These metallization layers generally include metal-containing lines, providing the inner-level electrical connection, and also include a plurality of inter-level connections, also referred to as vias, filled with an appropriate metal and providing the electrical connection between two neighboring stacked metallization layers, wherein the metal-containing lines and vias may also be commonly referred to as interconnects.

Due to the continuous reduction of the feature sizes of circuit elements in modern integrated circuits, the number of circuit elements for a given chip area, that is the packing density, also increases, thereby requiring an even larger increase in the number of electrical interconnections to provide the desired circuit functionality. Therefore, the number of stacked metallization layers usually increases as the number of circuit elements per chip area becomes larger and/or the sizes of the individual metal lines and vias are reduced. The fabrication of a plurality of metallization layers entails extremely challenging issues to be solved, such as mechanical, thermal and electrical reliability of up to twelve stacked metallization layers that may be employed on sophisticated aluminum-based microprocessors. However, semiconductor manufacturers are increasingly replacing the well-known metallization metal aluminum by a metal that allows higher current densities and hence allows a reduction in the dimensions of the interconnections and thus the number of stacked metallization layers. For example, copper and alloys thereof are metals generally considered to be viable candidates for replacing aluminum, due to their superior characteristics in view of higher resistance against electromigration and significantly lower electrical resistivity when compared with aluminum. Despite these advantages, copper also exhibits a number of disadvantages regarding the processing and handling of copper in a semiconductor facility. For instance, copper may not be efficiently applied onto a substrate in larger amounts by well-established deposition methods, such as chemical vapor deposition (CVD), and also may not be effectively patterned by the usually employed anisotropic etch procedures. Consequently, in manufacturing metallization layers including copper, the so-called damascene technique (single and dual) is preferably used, wherein a dielectric layer is first applied and then patterned to receive trenches and vias, which are subsequently filled with copper.

One approach in the conventional damascene technique that is frequently used is the so-called trench-first/via-last regime, in which a dielectric material (in advanced semiconductor devices, a dielectric material of reduced permittivity) is applied above semiconductor devices or above a lower lying metallization layer with an appropriate thickness. Thereafter, trenches are formed in an upper portion of the dielectric layer by photolithography and anisotropic etch techniques, wherein the trench width may be approximately 100 nm and even less in highly advanced semiconductor devices. Consequently, a sophisticated photolithography process is required, which significantly contributes to production costs. After the formation of the trenches, a further sophisticated photolithography process is performed for patterning vias within the trenches, wherein the vias extend through the remaining thickness of the dielectric material and thereby provide the connection to contact regions or metal lines of circuit elements or lower lying metallization layers. During this second sophisticated photolithography process, high precision is required for aligning the via pattern with the previously formed trenches, since a misaligned via structure causes at least performance degradation or may even lead to electrical failure. Thus, in the conventional trench-first/via-last approach, two sophisticated, and hence expensive, photolithography steps are involved, while the second step requires high precision for the correct alignment of the via structure with respect to the trenches, thereby bearing the potential for reliability concerns or even interconnect failure.

Similarly, the via-first/trench-last approach, which is also frequently used, requires two sophisticated photolithography processes. In a first step, the vias are formed in the dielectric material and subsequently the trenches are patterned by means of a second photolithography step, also requiring high precision in aligning the trenches with respect to the via structures. Consequently, also in this conventional approach, substantially the same problems are involved as are discussed above for the conventional trench-first/via-last approach.

In view of the above-identified problems, there is a need for an improved technique allowing the formation of reliable metal interconnects in highly scaled semiconductor devices.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique that enables the formation of metallization layers in semiconductor devices with significantly reduced complexity while nevertheless providing a high degree of precision in aligning a via structure with respect to a previously formed trench. For this purpose, a self-aligned manufacturing sequence for the via structure is provided wherein, after the formation of the trench structure, the anisotropic etch process for forming the via structure is based on sidewall spacers rather than a further lithography step, thereby significantly improving the alignment accuracy.

According to one illustrative embodiment of the present invention, a method comprises forming a trench in a dielectric layer, wherein the trench has a first trench portion of increased width at a via position in the trench. Moreover, spacers are formed on sidewalls of the trench portion of increased width and then the dielectric layer is anisotropically etched while using the spacers as an etch mask to form a via in the trench portion of increased width.

### BRIEF DESCRIPTION OF THE DRAWINGS

The invention may be understood by reference to the following description taken in conjunction with the accompanying drawings, in which like reference numerals identify like elements, and in which:

FIG. 1a schematically shows a top view of a trench including a portion of increased width at a position at which a via is to be formed, and a portion of non-increased width according to illustrative embodiments of the present invention;

FIGS. 1b, 1d, 1f, 1h, 1j and 1l schematically show cross-sectional views of the trench portion of increased width of FIG. 1a during various manufacturing stages in accordance with illustrative embodiments of the present invention;

FIGS. 1c, 1e, 2g, 1i, 1k and 1m schematically show cross-sectional views of the trench portion of non-increased width of FIG. 1a during various manufacturing stages, corresponding to the cross-sectional views of FIGS. 1b, 1d, 1f, 1h, 1j and 1l, respectively, according to illustrative embodiments of the present invention; and

FIGS. 2a-2c schematically show a semiconductor device including a metallization trench and via in a top view and cross-sectional views in which a hard mask is used for forming trenches in accordance with still further illustrative embodiments of the present invention.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention addresses the problem of process complexity and alignment issues during the formation of metallization layers of semiconductor devices, requiring the formation of metal trenches and metal vias in a dielectric layer. As previously explained, in highly advanced semiconductor devices, the so-called damascene technique is used for the formation of metallization layers, in which the dielectric layer under consideration is patterned to receive trenches and vias (dual damascene technique), which are then subsequently filled with an appropriate conductive material. Since typically two photolithography steps are required to obtain the trenches and the vias prior to filling in the conductive material, in particular in highly advanced semiconductor devices having feature sizes of 100 nm and even less for the lateral dimensions of trenches and vias, the corresponding photolithography processes are highly complex and thus extremely cost intensive. Moreover, the requirement of precisely aligning the vias with respect to the trenches may significantly contribute to reliability concerns and production yield losses, since even slightly misaligned vias may reduce the overall conductivity of the interconnect structure or may even cause a total failure of the semiconductor device. According to the present invention, however, a self-aligned process technique is used to align the via structure with respect to the trenches on the basis of process parameters that are defined by a deposition process rather than by the alignment accuracy of a photolithography process. Moreover, since the via etch process is performed on the basis of sidewall spacers formed within specifically designed areas of a trench, the provision of an etch mask formed by lithography is no longer necessary and may therefore significantly reduce the overall process complexity and thus production costs.

It should be appreciated that the present invention is highly advantageous for the formation of metallization layers of advanced semiconductor devices requiring low-k dielectric materials and highly conductive metals, such as copper and copper alloys, since here the feature sizes of trenches and vias may be on the order of magnitude of 100 nm and even less, so that any slight misalignment may significantly reduce device performance or may result in undue production yield losses. The principles of the present invention, however, may also be advantageously applied during the formation of less sophisticated semiconductor devices, thereby also contributing to reduced production costs and enhanced device reliability and performance. With reference to the accompanying drawings, further illustrative embodiments of the present invention will now be described in more detail.

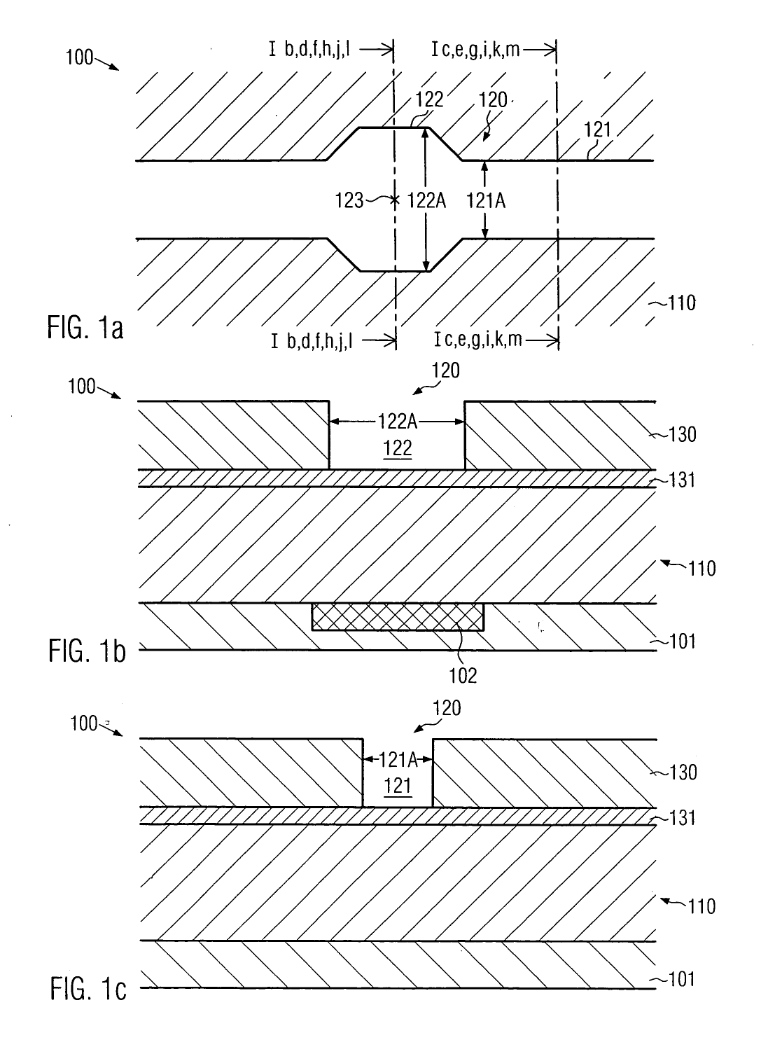

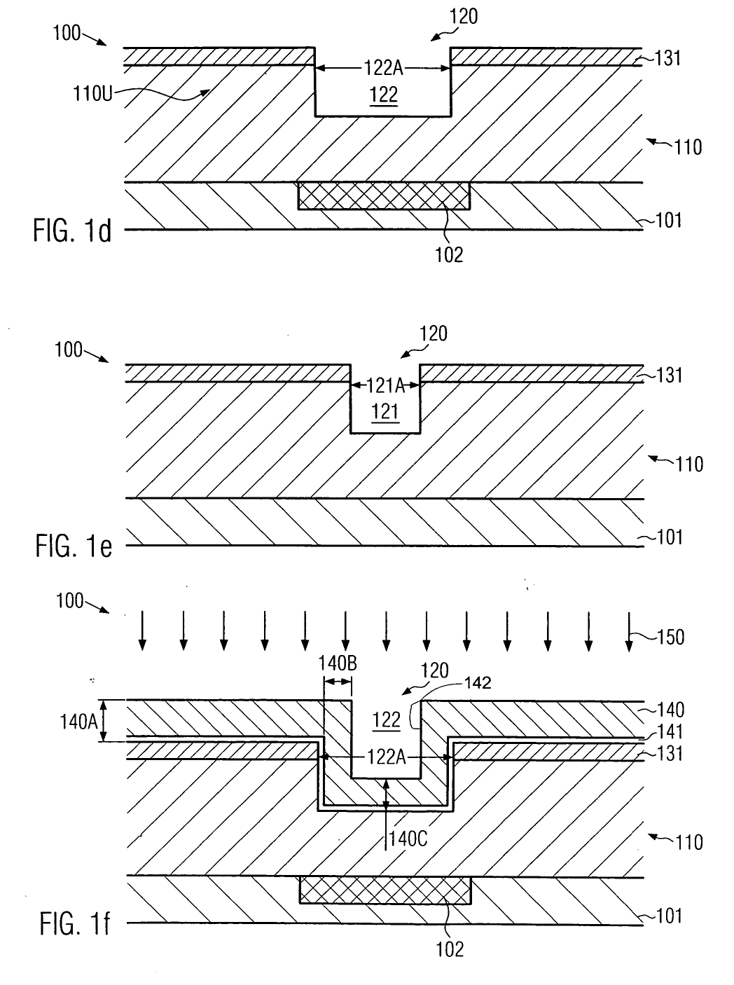

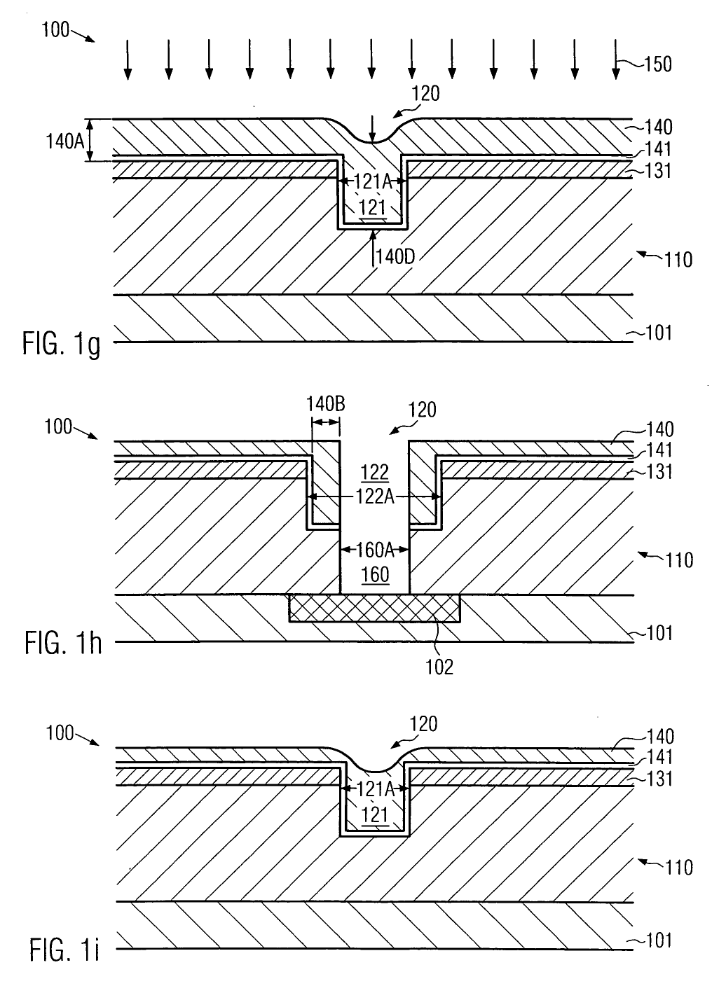

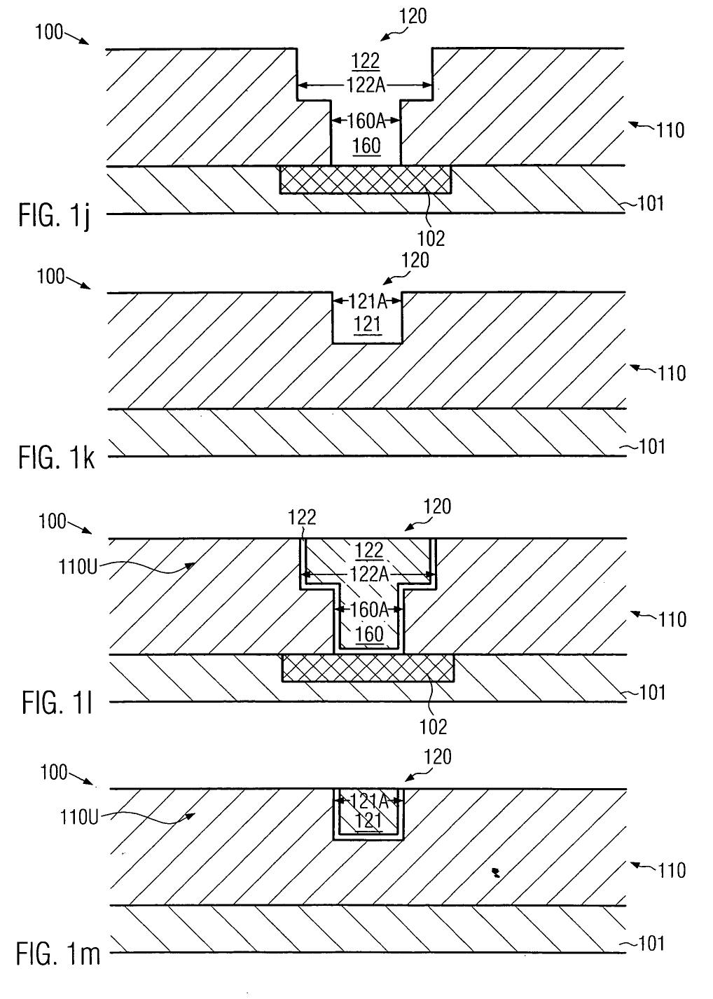

FIG. 1a schematically shows a top view of a semiconductor device 100 comprising a metallization layer 110 including a trench 120. The semiconductor device 100 may represent any semiconductor device including circuit elements that are connected in accordance with a specified circuit layout by the metallization layer 110, wherein, as previously described, a plurality of metallization layers 110 may be formed as a layer stack in the semiconductor device 100. For convenience, in the following detailed description, a single metallization layer will be referred to that provides the intra-level current flow by means of the trenches 120, while an inter-level current flow, that is, an electrical connection to a neighboring metallization layer or to any other contact region of a circuit element, is provided by a via (not shown in FIG. 1a), which, in the embodiment shown in FIG. 1a, has to be formed on a specified via position 123. Moreover, the metallization layer 110, at this manufacturing stage where actually no metal is filled in, may be comprised of any appropriate dielectric material, such as silicon dioxide, silicon nitride, low-k dielectric materials including appropriate polymer materials, porous materials and anorganic low-k dielectric materials, such as a compound of silicon, oxygen, carbon and hydrogen (SiCOH), silicon carbide, amorphous carbon, nitrogen-enriched silicon carbide, silicon oxynitride and the like. In illustrative embodiments, the metallization layer 110 may comprise a low-k dielectric material having a relative permittivity of approximately 3.5 or less.

The trench 120, which may not actually be formed in the metallization layer 110 in this manufacturing stage, but may be represented by any appropriate etch mask, as will be described in more detail with reference to FIGS. 1b and 1c, may comprise a first trench portion 121 having a lateral dimension or width 121a, which corresponds to a design width for accommodating a specified current density as may be encountered during the operation of the semiconductor device 100. Hereinafter, the first portion 121 having the lateral dimension 121a may also be referred to as a trench portion of non-increased width. Furthermore, the trench 120 may comprise a second portion 122 having a lateral dimension or width 122a that is increased compared to the lateral dimension 121a. Hence, the second portion 122 will also be referred to as a trench portion 122 of increased width. The position of the portion 122 of increased width within the trench 120 may be determined by the via position 123, at which a via opening is to be formed to a lower lying contact region or metal region. It should be appreciated that the specific geometrical configuration of the portion 122 of increased width may be selected in accordance with device and process requirements and is not restricted to the substantially polygonal shape as shown in FIG. 1a. For example, the portion 122 of increased width may have a substantially circular shape or the portion 122 may have an asymmetric configuration with respect to a longitudinal axis and/or a lateral axis of the trench 120. Consequently, unless specifically stated in the description and in the appended claims, the portion 122 of increased width should not be restricted to any specific geometrical configuration.

As previously pointed out, the lateral dimensions 121a, 122a may be on the order of 100 nm and even less for highly sophisticated semiconductor devices comprising transistor elements with a gate length of approximately 50 nm and even less. It should be appreciated that the principles of the present invention are not restricted to any specific magnitude of the lateral dimensions 121a, 122a and may also be applied to less critical applications and also to highly sophisticated future device generations requiring metal lines with dimensions of significantly less than 100 nm.

FIG. 1b schematically shows the semiconductor device 100 in a cross-sectional view taken along the line indicated by Ib, d, f, h, j, l in FIG. 1a. Hereby, the trench 120, i.e., in FIG. 1b, the cross-section of the portion 122 of increased width, is defined by a resist mask 130, which is formed above an anti-reflective coating (ARC) layer 131. Moreover, the semiconductor device 100 comprises a substrate 101, which may represent any appropriate substrate for the formation of microstructures including circuit elements and integrated circuits, such as microprocessors, storage chips, ASICs (application specific ICs) and the like. For instance, the substrate 101 may represent a silicon bulk substrate, a silicon-on-insulator (SOI) substrate or any other II-VI or III-V semiconductor substrate. The substrate 101 may have formed thereon any appropriate semiconductor layer that may enable the formation of corresponding microstructural features and circuit elements as is necessary for the application under consideration. The substrate 101 may have formed therein or thereon a contact or metal region 102, which is to represent any electrically conductive region that has to be connected to the metallization layer 110 according to device-specific requirements. For example, the region 102 may represent a metal line of a lower lying metallization layer, or the region 102 may represent a contact area of a circuit element, such as a transistor, capacitor and the like. Above the substrate 101, the metallization layer 110, which is in this manufacturing stage substantially a dielectric layer, is formed, wherein the metallization layer 110 is shown to be in an early manufacturing stage since metal-filled trenches and vias have still to be formed therein. As previously discussed, the metallization layer 110 may comprise any appropriate composition of dielectric materials as demanded by device requirements. In illustrative embodiments, the metallization layer 110 may comprise a low-k dielectric material, at least in an upper portion of the layer 110, in which metal-filled trenches are to be formed. It should further be appreciated that the dielectric material of the layer 110, also frequently referred to as interlayer dielectric (ILD), may be provided in the form of an appropriately designed layer stack so as to take into consideration process and device-specific constraints. For example, typically an etch stop layer (not shown) may be provided above the substrate 101, thereby covering the region 102 to act as a stop layer for controlling an anisotropic etch process for etching through the metallization layer 110. Similarly, the layer 110 may have any intermediate layers, such as etch stop layers, etch indicator layers and the like, that may facilitate the patterning of the layer 110 in accordance with process requirements. Furthermore, the layer 110 may comprise a cap layer, especially if low-k dielectric materials are used, in order to enhance the mechanical stability and other characteristics of the low-k dielectric material.

The semiconductor device 100 as shown in FIG. 1b may be manufactured in accordance with the following processes. After the formation of any circuit elements and/or other microstructural features including the region 102, the layer 110 may be formed by any appropriate manufacturing techniques, such as plasma enhanced chemical vapor deposition (PECVD), oxidation processes, spin-on techniques and the like. Thereafter, the ARC layer 131 may be formed for example on the basis of PECVD techniques, spin-on methods and the like, wherein the optical characteristics, such as index of refraction, extinction coefficient and layer thickness, are adjusted to significantly reduce any back-reflection of radiation for a specified exposure wavelength. For example, the ARC layer 131 may be comprised of a dielectric material that may allow convenient adjustment of its optical characteristics. In illustrative embodiments, materials such as silicon oxynitride, amorphous carbon, nitrogen-enriched silicon carbide, organic ARC materials and the like may be deposited, thereby controlling process parameters to obtain the required optical thickness with respect to the exposure wavelength. In other illustrative embodiments, the ARC layer 131 may be comprised of two or more layers to provide the desired behavior of the layer 131. For instance, in sophisticated applications requiring an exposure wavelength of 193 nm and even less, the resist materials used during the lithography for patterning the resist mask 130 may exhibit a high sensitivity to nitrogen and nitrogen radicals, thereby altering their photochemical behavior, which may result in resist mask irregularities, often referred to as resist poisoning. Hence, a substantially nitrogen-free material, at least as the uppermost layer of the ARC layer 131, may be provided to reduce a direct contact of nitrogen and the resist material.

After the formation of the ARC layer 131, a corresponding resist layer may be deposited, for instance by well-established spin-on techniques, and subsequently the resist layer may be exposed to a specified exposure wavelength on the basis of a photomask that has formed therein a trench pattern corresponding to the trench 120, i.e., the corresponding photomask has a trench pattern including portions that correspond to the portions 121 of non-increased width and to portions 122 of increased width. After the exposure of the resist layer and any post-exposure processes, the resist layer may be developed to form the resist mask 130 having formed therein the trench 120.

FIG. 1c schematically shows the semiconductor device 100 in a cross-sectional view according to the section indicated in FIG. 1a by Ic, e, g, i, k, m, and therefore represents the portion 121 of non-increased width. Consequently, the device 100 comprises the resist mask 130, which defines the portion 121 having the width 121a.

FIG. 1d schematically shows the semiconductor device 100 with the resist mask 130 removed and with the trench 122 formed in the ARC layer 131 and within an upper portion 110u of the layer 110. The trench portion 122 of increased width has substantially the width 122a as defined by the resist mask 130 (FIG. 1b). The device 100, as shown in FIG. 1d, may be formed by an anisotropic etch process on the basis of well-established recipes wherein the resist mask 130 may act as an etch mask. The anisotropic etch process may be controlled to stop at a desired depth within the layer 110, which may, for instance, be accomplished on the basis of any etch stop layer (not shown), an etch indicator layer (not shown) or on the basis of etch time and etch rate control.

FIG. 1e schematically shows the device 100 after the above-described process sequence with a cross-section taken along the line of FIG. 1a through the second portion 121 having the non-increased width. Hence, the portion 121 is also formed within the upper portion 110u of the layer 110 and exhibits substantially the width 121a as defined by the resist mask 130 (FIG. 1c).

FIG. 1f schematically shows a cross-section through the trench portion 122 of increased width, when the semiconductor device 100 is in a further advanced manufacturing stage. A spacer layer 140 is formed on the ARC layer 131 and within the portion 122. The spacer layer 140 may be comprised of any appropriate material that may enable its deposition in a substantially conformal fashion and which may be removed in a later manufacturing stage without undue influence on the layer 110. For example, the spacer layer 140 may be comprised of an organic polymer material that may be deposited by chemical vapor deposition techniques, thereby achieving a high degree of conformality while nevertheless exhibiting a moderately high etch selectivity to a plurality of dielectric materials and also to low-k dielectric materials. In other illustrative embodiments, the spacer layer 140 may comprise a thin liner material, such as a liner 141, which may be deposited by advanced deposition techniques, such as PECVD. In one illustrative embodiment, the liner 141 may be comprised of a material exhibiting a moderately high etch selectivity to the material of the spacer layer 140, when, for instance, the material of the layer 140 may not have the desired high etch selectivity with respect to the dielectric material of the layer 110. For example, the liner 141 may be provided in the form of a thin silicon dioxide layer having a thickness of a few nanometers or less. Irrespective of whether the liner 141 is provided, the spacer layer 140 is formed in a highly conformal manner wherein, depending on structural characteristics and deposition process parameters, a thickness 140a on exposed horizontal portions may differ from a thickness 140b of the layer 140 on sidewalls of the trench portion 122. The layer portion of the spacer layer 140 at the sidewalls of the trench portion 122 may be considered as a spacer element 142, which may define, in combination with the increased width 122a, the finally obtained lateral dimension of a via to be formed within the trench portion 122. Moreover, as shown, a thickness 140c at the bottom of the trench portion 122 may differ from the corresponding dimensions 140a and 140b due to the kinetic-specific conditions during the deposition of the spacer layer 140. It should be appreciated, however, that deposition recipes for a wide variety of materials are well known and the corresponding dimensions 140a, 140b and 140c may readily be adjusted on the basis of experimental and/or theoretical data so that especially the thickness 140b of the spacer element 142 may be predicted with high precision and may also be controlled within tight process margins on the basis of well-established recipes.

FIG. 1g schematically shows the semiconductor device 100 after the formation of the spacer layer 140, wherein the portion 121 of non-increased width is substantially completely filled with the material of the spacer layer 140, since the width 120a is significantly less than the width 122a. Consequently, during the highly conformal deposition process for forming the spacer layer 140, the trench portion 121 is substantially filled, while the increased width 122a ensures the formation of the spacer elements 142 with the specified width 140b. It should be appreciated that typically the width 121a, representing the width of a metal line to be formed in the layer 110, may substantially be determined by design requirements for the semiconductor device 100 under consideration. Thus, the thickness 140b and the hence the width of the spacer elements 142, and thus the thicknesses 140a and 140c, as these dimensions are substantially determined by the deposition parameters, may be selected to provide a substantially complete filling of the trench portion 121 without undue void formation therein. For example, the width 121a may be given to approximately 100 nm on the basis of design rules of the device 100 and hence the thickness 140b, resulting from the deposition of the spacer material on substantially vertical sidewalls of a trench opening, may be selected to be approximately half of the width 121a or more, thereby ensuring a substantially non-conformal deposition behavior within the trench portion 121. On the other hand, since the thickness 140b of the spacer elements 142 determines, in combination with the width 122a, the lateral dimension of the via to be formed within the trench portion 122, the width 122a and thus the geometrical configuration of the trench portion 122 may be selected so that a sufficiently dimensioned thickness 140b is obtained that meets both the requirement for substantially completely filling the trench portion 121 and providing the desired lateral target dimension for the via opening still to be formed.

For the above example, the thickness 140b may be selected to be, for instance, 60 nm, thereby providing the required fill behavior during the deposition of the spacer layer 140 within the trench portion 121. If, on the other hand, a lateral dimension of the via opening of, for instance, 80 nm is desired, the trench portion 122 may be designed such that the target width 122a corresponds to 200 nm. It should be appreciated that the above example is of illustrative nature only and other correlations may be established so as to adapt the thickness 140b and the width 122a for a given non-increased width 121a. Thus, in some illustrative embodiments, the fill behavior of a deposition process of interest for a specific spacer material under consideration may be determined, for instance on the basis of corresponding test runs with subsequent cross-sectional analysis so as to identify, for instance, a minimum thickness of the spacer layer 140, which is required for a substantially void-free filling of the trench 121. Once the corresponding minimum required thickness 140a is determined, a specific target thickness for the spacer layer 140 in combination with a required target width 122a may then be selected to achieve the required lateral dimension of a via opening.

After the formation of the spacer layer 140, which may also be denoted as a “via mask liner,” the semiconductor device 100 is subjected to an anisotropic etch process 150 to open the spacer layer 140 at the bottom of the trench portion 122, thereby removing the material having the thickness 140c that is significantly less than a corresponding thickness 140d of the spacer layer 140 formed in and above the trench portion 121 (FIG. 1g). Consequently, during the anisotropic etch process 150, the trench portion 121 is protected, while after opening the bottom of the trench portion 122, and possibly of an optional etch stop layer such as the liner 141, the material of the layer 110 may be etched, while the spacer elements 142 act as an etch mask, thereby defining the lateral dimension of the via opening.

In some illustrative embodiments, the anisotropic etch process 150 may comprise two or more individual anisotropic etch steps, for instance for etching through the spacer layer 140 and for etching through the layer 110, when these materials exhibit a significantly different etch behavior with respect to a single etch recipe. For example, an anisotropic etch process step may be used to rapidly etch through the spacer layer 140 and a different etch recipe may be used if a high removal rate for the layer 110 may not be obtained by the recipe of the first anisotropic etch step. For instance, when the liner 141 is comprised of well-known dielectrics, such as silicon dioxide, silicon nitride, well-established anisotropic etch processes may be used for silicon dioxide and silicon nitride, provided that both layers, i.e., the liner 141 and the spacer layer 140, when comprised of silicon dioxide and silicon nitride, respectively, may be deposited at sufficiently low temperatures so as to not unduly affect the semiconductor device 100. In other illustrative embodiments, appropriate organic materials may be used for the spacer layer 140 or even metal-containing layers may be used, such as titanium, titanium nitride, tantalum, tantalum nitride and the like, which may be deposited by well-established sputter deposition techniques, as are also used for the formation of barrier layers in copper-based metallization layers.

FIGS. 1h and 1i schematically show cross-sectional views of the semiconductor device 100 after the completion of the anisotropic etch process 150. In FIG. 1h, the semiconductor device 100 now comprises a via 160 having a lateral dimension 160a that substantially corresponds to the difference between the width 122a and two times the thickness 140b, as is also explained above. Moreover, depending on the specifics of the anisotropic etch process 150, the spacer layer 140 may have been “consumed” to a specific degree, thereby providing a reduced spacer layer 140, wherein even a significant consumption of the spacer layer 140 may have occurred as long as the bottom of the trench portion 121 (FIG. 1i) remains covered during the anisotropic etch process 150. In other embodiments, the liner 141 may be provided and may exhibit a high resistivity against an etch attack of the anisotropic etch process 150 so that even an excessive material removal of the material of the spacer layer 140 during the anisotropic etch process 150 may not unduly affect the trench portion 121 and the corresponding areas of the portion 122, which are initially covered by the spacer elements 142.

Irrespective of the etch strategy, the process for forming the via 160 is based on design and deposition specifics, such as the width 122a and the thickness 140b, so that the via 160 is self-aligned to the trench 120 with high precision, wherein a single photolithography process is sufficient to form the trench 120 and the via 160 precisely aligned therein.

After the formation of the via 160, which may also include the opening of any etch stop layer formed on the region 102, the residues of the spacer layer 140 and, if provided, the liner 141 may be removed wherein, as previously explained, a moderately high etch selectivity between the material of the spacer layer 140 and the dielectric of the layer 110 may be exploited, or wherein the residue of the spacer layer 140 may be removed by an isotropic etch process with high etch selectivity to the liner 141. Thereafter, the liner 141 may be removed by a further etch process, for instance an isotropic etch process. For example, if the liner 141 is provided as a thin silicon dioxide layer, the removal may be performed on the basis of diluted fluoric acid (HF) without significantly affecting the trench portions 122 and 121. Subsequently, the ARC layer 131 may be removed by any appropriate etch process in accordance with well-established process recipes.

FIGS. 1j and 1k schematically show cross-sectional views of the trench portions 122 and 121, respectively, after the completion of the above-described process sequence. Hence, the semiconductor device 100 comprises the trench 122 having substantially the width 122a and formed therein the via opening 160 having the lateral dimension 160a, while the trench portion 121 substantially exhibits the lateral dimension 121a.

Thereafter, the further manufacturing process of the semiconductor device 100 may be continued in accordance with device requirements. For example, in advanced copper-based semiconductor devices 100, the further manufacturing process may involve the deposition of an appropriate barrier layer, followed by a seed layer to prepare the semiconductor device 100 for a subsequent electrochemical deposition process to fill in the bulk of a highly conductive copper or copper alloy metal into the trench portions 122 and 121 and the via 160 in a single deposition process. For example, highly advanced and well-established electroplating recipes may be used to fill the via 160 and the trench 120 in a substantially bottom-up-fashion after the barrier layer and the seed layer have been formed.

FIGS. 1l and 1m schematically show cross-sectional views of the semiconductor device 100 after the completion of the above-described process sequence for filling in a metal and the removal of any excess materials of the metal and the barrier and seed layer. Hence, the semiconductor device 100 comprises the metallization layer 110 having formed in its upper portion 110u the trench 120 filled with a metal, such as copper or copper alloy, with a barrier layer 123 formed on the sidewalls and the bottom of the trench 120, except for a portion at which the metal-filled via 160 is connected to the trench portion 122.

As a result, highly reliable self-aligned via structures may be formed with a single photolithography process, wherein appropriately designed trench portions of increased width are formed at positions at which the via has to be formed. Due to the reduced process complexity and high alignment precision, overall costs may significantly be reduced, while reliability and yield may improve.

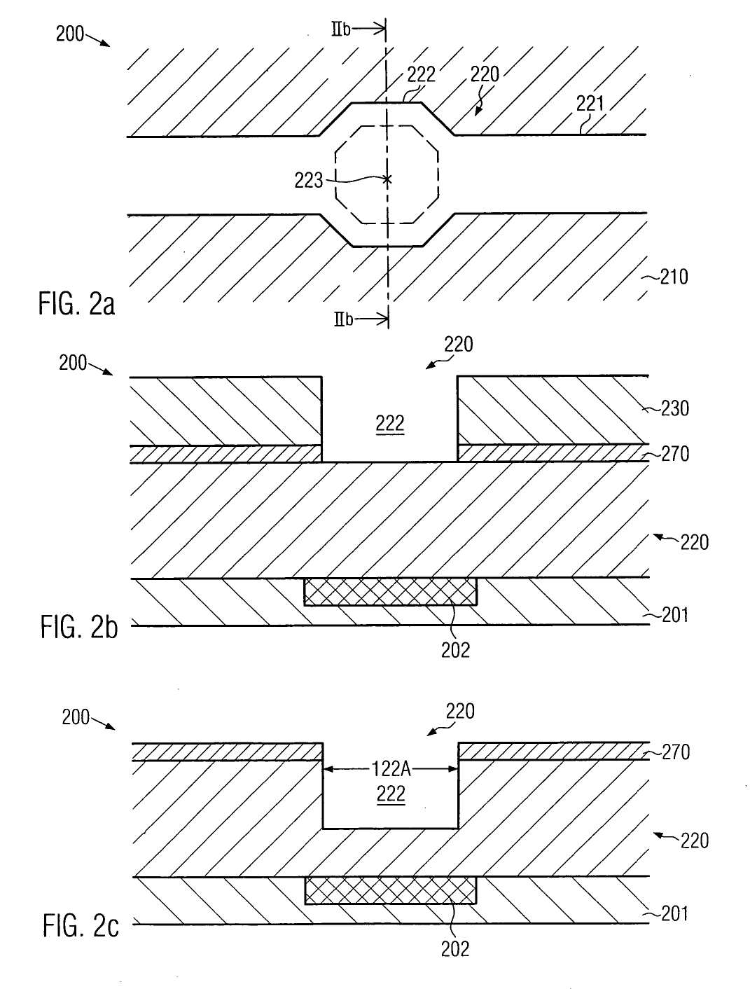

With reference to FIGS. 2a-2c, further illustrative embodiments of the present invention will now be described, wherein an even enhanced accuracy of the trench patterning process may be achieved, in that a hard mask is used for patterning of the trenches instead of a resist mask, as is shown in FIGS. 1b and 1c.

FIG. 2a schematically shows a semiconductor device 200, which may have substantially the same configuration as is also described with reference to FIG. 1a. Thus, the semiconductor device 200 may comprise a metallization layer 210 with a trench 220 defined thereabove by means of a resist mask, similar to that shown in FIGS. 1b and 1c. The trench 220 comprises a portion 221 of non-increased width and a portion 222 of increased width, which is located at a position 223, at which a via is to be formed within the trench 220, as is indicated by the dashed lines.

FIG. 2b schematically shows a cross-sectional view of the device 200 wherein, for convenience, only the cross-section along the line IIb corresponding to the portion 222 of increased width is illustrated. The device 200 may comprise a resist mask 230 and a hard mask layer 270 having formed therein the trench 220. Moreover, the semiconductor device 200 may comprise the substrate 201, which may be configured similarly as is described with reference to the substrate 101, having formed therein or thereon a contact or metal region 202, to which an electrical connection is to be formed by means of a via.

Typically the device 200 as shown in FIG. 2b may be formed on the basis of well-established process recipes, wherein additionally the hard mask layer 270 may be deposited above the metallization layer 210. The hard mask layer 270 may have a pronounced etch selectivity with respect to the dielectric material of the layer 210 so as to act as an etch mask during a subsequent anisotropic trench etch process. For example, the hard mask layer 270 may be comprised of any metallic or non-metallic material that exhibits the required etch selectivity to the dielectric material of the layer 210. Moreover, in some embodiments, the hard mask layer 270 may be comprised of a plurality of layers or materials to provide the desired characteristics. In some illustrative embodiments, the hard mask layer 270 may be designed to also act as an ARC layer during the patterning of the resist mask 230. Providing the hard mask layer 270 is advantageous in that the photolithography process for patterning the resist layer 230 may specifically be designed to enhance the imaging of the photomask into the resist layer, without necessitating taking into consideration etch-specific criteria of the resist mask 230, as this mask now only serves to pattern the hard mask layer 270. For example, in highly sophisticated applications, the resist mask 230 may be used for exposure wavelengths of 193 nm and even less, which may require a moderately low thickness of the resist mask 230, which may, in some embodiments described with reference to FIGS. 1a-1m, compromise the etch fidelity in transferring the trench 220 into the metallization layer 210. Thus, by adapting the resist layer according to the photolithography-specific constraints, the photolithography process may be made more efficient and precise so that the corresponding shape and dimensions of the trench 220 may reliably be transferred into the hard mask layer 270. Subsequently, the resist mask 230 may be removed and an anisotropic etch process may be performed on the basis of the patterned hard mask layer 270.

FIG. 2c schematically shows the semiconductor device 200 after the completion of the anisotropic etch process based on the hard mask layer 270. Consequently, the device 200 comprises a trench 220 formed in an upper portion 210u of the dielectric material of the metallization layer 210. Due to the superior etch resistivity of the hard mask layer 270 compared to, for instance, the resist mask 130 (FIGS. 1b and 1c), an enhanced accuracy in transferring the trench 220 into the layer 210 is obtained, which may allow further device scaling substantially without reliability and yield loss. Thereafter, the further processing of the device 200 may be continued as is described with reference to FIGS. 1d-1m. In particular, the self-aligned via mask formation process may be performed as previously explained.

As a result, the present invention provides an enhanced technique that enables the formation of trenches and vias with a single lithography process, since the formation of the via structure may be performed in a self-aligned fashion using a correspondingly designed spacer layer or via mask liner, in combination with an appropriate trench design. Due to the provision of trench portions of increased width at positions at which vias are to be formed within the trench, the via etch process may be performed on the basis of spacer elements without any further alignment or lithography procedures.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a trench in a dielectric layer, said trench having a first trench portion of increased width at a via position in said trench;
forming spacers on the sidewalls of said first trench portion of increased width; and
anisotropically etching said dielectric layer using said spacers as an etch mask to form a via in said first trench portion of increased width.

2. The method of claim 1, wherein forming said spacers comprises conformally depositing a spacer layer to form said spacers and to substantially completely fill second trench portions having a width less than said increased width of said first trench portion.

3. The method of claim 2, further comprising adjusting a lateral size of said first trench portion of increased width and a thickness of said spacer layer to correspond to a lateral target dimension of said via.

4. The method of claim 3, further comprising adjusting the lateral size of said first trench portion of increased width and a thickness of said spacer layer on the basis of a target width of said second trench portions to substantially completely fill said second trench portions.

5. The method of claim 1, wherein forming a trench in said dielectric layer comprises forming an etch mask above said dielectric layer, said etch mask comprising a mask for said first trench portion and a mask for said second trench portions, and anisotropically etching into said dielectric layer on the basis of said etch mask.

6. The method of claim 5, wherein said etch mask is a resist mask.

7. The method of claim 5, wherein forming said etch mask comprises forming a hard mask layer above said dielectric layer, forming a resist mask above said hard mask layer and patterning said hard mask layer with said resist mask to form said etch mask.

8. The method of claim 1, further comprising removing said spacers after forming said via.

9. The method of claim 2, further comprising forming an etch stop layer prior to depositing said spacer layer.

10. The method of claim 2, wherein said second portions of said trench have a lateral dimension of approximately 100 nm or less.

11. The method of claim 1, further comprising filling a metal into said trench and said via in a common deposition process.

12. The method of claim 11, wherein said metal comprises copper.
